(19) United States
(12) Patent Application Publication
(10) Pub. No.: US 2025/0105862 A1
(43) Pub. Date: Mar. 27, 2025

(54) Electronic Device Having Switched Filter Combining

(71) Applicant: Apple Inc., Cupertino, CA (US)

(72) Inventors: Bradley D. Scoles, Morgan Hill, CA (US); Qishan Yu, San Jose, CA (US); Christopher J. Huber, North Reading, MA (US)

(21) Appl. No.: 18/807,791

(22) Filed: Aug. 16, 2024

Related U.S. Application Data
(60) Provisional application No. 63/585,494, filed on Sep. 26, 2023.

(51) Int. Cl. H04B 1/04; H03F 3/24

(52) U.S. Cl. CPC H04B 1/04; H03F 3/245; H03F 2200/171; H03F 2200/294; H03F 2200/451; H04B 2001/045

(57) ABSTRACT

An electronic device may include a radio-frequency front end (RFFE) module coupled to antenna(s). The module may have a power amplifier, a transmit switch, a receive switch, low noise amplifiers, and an antenna switch. The transmit switch may be coupled to the antenna switch over transmit paths. The antenna switch may be coupled to the low noise amplifiers over receive paths. Filters on different transmit paths may have passbands overlapping the transmit bands of respective first and second frequency bands. A filter on the receive path may have a passband overlapping the receive bands of the first and second frequency bands. The antenna switch may have multiple throws for concurrently coupling one of the transmit paths and one of the receive paths to the antenna(s). Combining filters and switching in this way may minimize the number of low noise amplifiers and filters on the module without sacrificing performance.

This application claims the benefit of U.S. Provisional Patent Application No. 63/585,494, filed Sep. 26, 2023, which is hereby incorporated by reference herein in its entirety

### FIELD

This disclosure relates generally to electronic devices, including electronic devices with wireless communications circuitry.

### BACKGROUND

Electronic devices are often provided with wireless communications capabilities. An electronic device with wireless communications capabilities has wireless communications circuitry with an antenna.

During wireless transmission, it can be desirable for the wireless communications circuitry to be able to convey radio-frequency signals in different frequency bands over the antenna. However, in practice, it can be difficult to provide satisfactory isolation and wireless performance across each of the frequency bands while minimizing space and power consumed by the wireless circuitry.

### SUMMARY

An electronic device may include wireless circuitry for performing wireless communications. The wireless circuitry may include a transceiver, one or more antennas, and a radio-frequency front end (RFFE) module coupled between the transceiver and the antenna(s). The RFFE module may have a power amplifier, a transmit switch, a receive switch, low noise amplifiers, and an antenna switch.

The transmit switch may have an input terminal coupled to an output of the power amplifier. The transmit switch may have output terminals coupled to transmit terminals of the antenna switch over transmit paths. The receive switch may have input terminals coupled to receive terminals of the antenna switch over receive paths. The low noise amplifiers may be disposed on the receive paths. The antenna switch may have an antenna terminal coupled to the antenna(s).

Filter circuitry may be disposed on the transmit and receive paths. For example, a first filter may be disposed on a first transmit path, a second filter may be disposed on a second transmit path, and a third filter may be disposed on a receive path. The first filter may have a first passband overlapping the transmit band of a first frequency band. The first frequency band may have a receive band higher than the transmit band. The second filter may have a second passband overlapping the transmit band of a second frequency band. The second frequency band may have a receive band lower than the transmit band of the second frequency band and higher than the receive band of the first frequency band. The third filter may have a third passband overlapping the both the receive band of the first frequency band and the receive band of the second frequency band. The antenna switch may have multiple throws for concurrently coupling one of the transmit terminals and one of the receive terminals to the antenna terminal. Combining filters and switching in this way may minimize the number of low noise amplifiers and filters on the RFFE module without sacrificing performance.

An aspect of the disclosure provides wireless circuitry. The wireless circuitry can include an antenna configured to convey radio-frequency signals in a first frequency band and a second frequency band that is higher than the first frequency band. The wireless circuitry can include a first filter communicably coupled to the antenna and having a first passband overlapping a transmit band of the first frequency band. The wireless circuitry can include a second filter communicably coupled to the antenna and having a second passband overlapping a transmit band of the second frequency band. The wireless circuitry can include a third filter communicably coupled to the antenna and having a third passband overlapping a receive band of the first frequency band and a receive band of the second frequency band.

An aspect of the disclosure provides a radio-frequency front end (RFFE) module. The RFFE module can include a power amplifier. The RFFE module can include a first switch having an input terminal coupled to an output of the power amplifier, a first output terminal, and a second output terminal. The RFFE module can include a second switch having a first terminal coupled to the first output terminal over a first signal path, a second terminal coupled to the second output terminal over a second signal path, and a third terminal coupled to a third signal path. The RFFE module can include a first filter disposed on the first signal path and having a first passband that overlaps a first transmit band of a first frequency band, the first frequency band having a first receive band that is higher than the first transmit band. The RFFE module can include a second filter disposed on the second signal path and having a second passband that overlaps a second transmit band of a second frequency band, the second frequency band having a second receive band that is lower than the second transmit band. The RFFE module can include a third filter disposed on the third signal path and having a third passband that overlaps the first receive band and the second receive band.

An aspect of the disclosure provides an electronic device. The electronic device can include an antenna configured to convey radio-frequency signals in a first transmit band, a first receive band, a second transmit band different from the first transmit band, and a second receive band different from the first receive band. The electronic device can include a power amplifier. The electronic device can include a first switch having a first terminal, a second terminal, and a third terminal, the first terminal being coupled to an output of the power amplifier. The electronic device can include a second switch having a fifth terminal coupled to the second terminal over a first signal path, a sixth terminal coupled to the third terminal over a second signal path, a seventh terminal coupled to a third signal path, and an eighth terminal communicably coupled to the antenna. The electronic device can include a first filter disposed on the first signal path and having a first passband overlapping the first transmit band. The electronic device can include a second filter disposed on the second signal path and having a second passband overlapping the second transmit band. The electronic device can include a third filter disposed on the third signal path and having a third passband overlapping the first receive band and the second receive band.

### BRIEF DESCRIPTION OF THE DRAWINGS

FIG. 1 is a perspective view of an illustrative electronic device in accordance with some embodiments.

FIG. 2 is a schematic diagram of illustrative circuitry in an electronic device in accordance with some embodiments.

FIG. 3 is a top interior view of an illustrative electronic device having antennas at different locations within the electronic device in accordance with some embodiments.

FIG. 4 is a circuit diagram of an illustrative radio-frequency front end having combined and switched filters for transmitting and receiving radio-frequency signals in different frequency bands in accordance with some embodiments.

FIGS. 5 and 6 are frequency diagrams illustrating the passbands of combined and switched filters of the type shown in FIG. 4 in accordance with some embodiments.

FIG. 7 is a flow chart of illustrative operations involved in using a radio-frequency front end having combined and switched filters for transmitting and receiving radio-frequency signals in different frequency bands over the same antenna in accordance with some embodiments.

### DETAILED DESCRIPTION

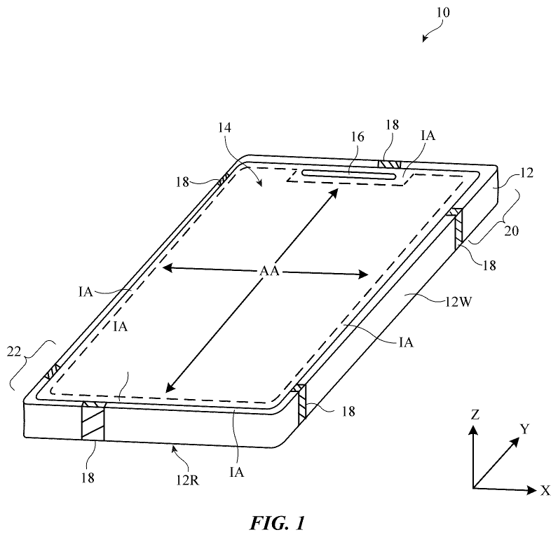

An electronic device such as electronic device 10 of FIG. 1 may be provided with wireless circuitry that includes antennas. The antennas may be used to transmit and/or receive wireless radio-frequency signals.

Device 10 may be a portable electronic device or other suitable electronic device. For example, device 10 may be a laptop computer, a tablet computer, a somewhat smaller device such as a wrist-watch device, pendant device, headphone device, earpiece device, headset device, or other wearable or miniature device, a handheld device such as a cellular telephone, a media player, or other small portable device. Device 10 may also be a set-top box, a desktop computer, a display into which a computer or other processing circuitry has been integrated, a display without an integrated computer, a wireless access point, a wireless base station, an electronic device incorporated into a kiosk, building, or vehicle, or other suitable electronic equipment.

Device 10 may include a housing such as housing 12. Housing 12, which may sometimes be referred to as a case, may be formed of plastic, glass, ceramics, fiber composites, metal (e.g., stainless steel, aluminum, etc.), other suitable materials, or a combination of these materials. In some situations, parts of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may, if desired, have a display such as display 14. Display 14 may be mounted on the front face of device 10. Display 14 may be a touch screen that incorporates capacitive touch electrodes or may be insensitive to touch. The rear face of housing 12 (i.e., the face of device 10 opposing the front face of device 10) may have a substantially planar housing wall such as rear housing wall 12R (e.g., a planar housing wall). Rear housing wall 12R may have slots that pass entirely through the rear housing wall and that therefore separate portions of housing 12 from each other. Rear housing wall 12R may include conductive portions and/or dielectric portions. If desired, rear housing wall 12R may include a planar metal layer covered by a thin layer or coating of dielectric such as glass, plastic, sapphire, or ceramic (e.g., a dielectric cover layer). Housing 12 may also have shallow grooves that do not pass entirely through housing 12. The slots and grooves may be filled with plastic or other dielectric materials. If desired, portions of housing 12 that have been separated from each other (e.g., by a through slot) may be joined by internal conductive structures (e.g., sheet metal or other metal members that bridge the slot).

Housing 12 may include peripheral housing structures such as peripheral structures 12W. Conductive portions of peripheral structures 12W and conductive portions of rear housing wall 12R may sometimes be referred to herein collectively as conductive structures of housing 12. Peripheral structures 12W may run around the periphery of device 10 and display 14. In configurations in which device 10 and display 14 have a rectangular shape with four edges, peripheral structures 12W may be implemented using peripheral housing structures that have a rectangular ring shape with four corresponding edges and that extend from rear housing wall 12R to the front face of device 10 (as an example). In other words, device 10 may have a length (e.g., measured parallel to the Y-axis), a width that is less than the length (e.g., measured parallel to the X-axis), and a height (e.g., measured parallel to the Z-axis) that is less than the width. Peripheral structures 12W or part of peripheral structures 12W may serve as a bezel for display 14 (e.g., a cosmetic trim that surrounds all four sides of display 14 and/or that helps hold display 14 to device 10) if desired. Peripheral structures 12W may, if desired, form sidewall structures for device 10 (e.g., by forming a metal band with vertical sidewalls, curved sidewalls, etc.).

Peripheral structures 12W may be formed from a conductive material such as metal and may therefore sometimes be referred to as peripheral conductive housing structures, conductive housing structures, peripheral metal structures, peripheral conductive sidewalls, peripheral conductive sidewall structures, conductive housing sidewalls, peripheral conductive housing sidewalls, sidewalls, sidewall structures, or a peripheral conductive housing member (as examples). Peripheral conductive housing structures 12W may be formed from a metal such as stainless steel, aluminum, alloys, or other suitable materials. One, two, or more than two separate structures may be used in forming peripheral conductive housing structures 12W.

It is not necessary for peripheral conductive housing structures 12W to have a uniform cross-section. For example, the top portion of peripheral conductive housing structures 12W may, if desired, have an inwardly protruding ledge that helps hold display 14 in place. The bottom portion of peripheral conductive housing structures 12W may also have an enlarged lip (e.g., in the plane of the rear surface of device 10). Peripheral conductive housing structures 12W may have substantially straight vertical sidewalls, may have sidewalls that are curved, or may have other suitable shapes. In some configurations (e.g., when peripheral conductive housing structures 12W serve as a bezel for display 14), peripheral conductive housing structures 12W may run around the lip of housing 12 (i.e., peripheral conductive housing structures 12W may cover only the edge of housing 12 that surrounds display 14 and not the rest of the sidewalls of housing 12).

Rear housing wall 12R may lie in a plane that is parallel to display 14. In configurations for device 10 in which some or all of rear housing wall 12R is formed from metal, it may be desirable to form parts of peripheral conductive housing structures 12W as integral portions of the housing structures forming rear housing wall 12R. For example, rear housing wall 12R of device 10 may include a planar metal structure and portions of peripheral conductive housing structures 12W on the sides of housing 12 may be formed as flat or curved vertically extending integral metal portions of the planar metal structure (e.g., housing structures 12R and 12 W may be formed from a continuous piece of metal in a unibody configuration). Housing structures such as these may, if desired, be machined from a block of metal and/or may include multiple metal pieces that are assembled together to form housing 12. Rear housing wall 12R may have one or more, two or more, or three or more portions. Peripheral conductive housing structures 12W and/or conductive portions of rear housing wall 12R may form one or more exterior surfaces of device 10 (e.g., surfaces that are visible to a user of device 10) and/or may be implemented using internal structures that do not form exterior surfaces of device 10 (e.g., conductive housing structures that are not visible to a user of device 10 such as conductive structures that are covered with layers such as thin cosmetic layers, protective coatings, and/or other coating/cover layers that may include dielectric materials such as glass, ceramic, plastic, or other structures that form the exterior surfaces of device 10 and/or serve to hide peripheral conductive housing structures 12W and/or conductive portions of rear housing wall 12R from view of the user).

Display 14 may have an array of pixels that form an active area AA that displays images for a user of device 10. For example, active area AA may include an array of display pixels. The array of pixels may be formed from liquid crystal display (LCD) components, an array of electrophoretic pixels, an array of plasma display pixels, an array of organic light-emitting diode display pixels or other light-emitting diode pixels, an array of electrowetting display pixels, or display pixels based on other display technologies. If desired, active area AA may include touch sensors such as touch sensor capacitive electrodes, force sensors, or other sensors for gathering a user input.

Display 14 may have an inactive border region that runs along one or more of the edges of active area AA. Inactive area IA of display 14 may be free of pixels for displaying images and may overlap circuitry and other internal device structures in housing 12. To block these structures from view by a user of device 10, the underside of the display cover layer or other layers in display 14 that overlap inactive area IA may be coated with an opaque masking layer in inactive area IA. The opaque masking layer may have any suitable color. Inactive area IA may include a recessed region such as notch 24 that extends into active area AA. Active area AA may, for example, be defined by the lateral area of a display module for display 14 (e.g., a display module that includes pixel circuitry, touch sensor circuitry, etc.). The display module may have a recess or notch in upper region 20 of device 10 that is free from active display circuitry (i.e., that forms notch 24 of inactive area IA). Notch 24 may be a substantially rectangular region that is surrounded (defined) on three sides by active area AA and on a fourth side by peripheral conductive housing structures 12W. One or more sensors may be aligned with notch 24 and may transmit and/or receive light through display 14 within notch 24.

Display 14 may be protected using a display cover layer such as a layer of transparent glass, clear plastic, transparent ceramic, sapphire, or other transparent crystalline material, or other transparent layer(s). The display cover layer may have a planar shape, a convex curved profile, a shape with planar and curved portions, a layout that includes a planar main area surrounded on one or more edges with a portion that is bent out of the plane of the planar main area, or other suitable shapes. The display cover layer may cover the entire front face of device 10. In another suitable arrangement, the display cover layer may cover substantially all of the front face of device 10 or only a portion of the front face of device 10. Openings may be formed in the display cover layer. For example, an opening may be formed in the display cover layer to accommodate a button. An opening may also be formed in the display cover layer to accommodate ports such as speaker port 16 in notch 24 or a microphone port. Openings may be formed in housing 12 to form communications ports (e.g., an audio jack port, a digital data port, etc.) and/or audio ports for audio components such as a speaker and/or a microphone if desired.

Display 14 may include conductive structures such as an array of capacitive electrodes for a touch sensor, conductive lines for addressing pixels, driver circuits, etc. Housing 12 may include internal conductive structures such as metal frame members and a planar conductive housing member (sometimes referred to as a conductive support plate or backplate) that spans the walls of housing 12 (e.g., a substantially rectangular sheet formed from one or more metal parts that is welded or otherwise connected between opposing sides of peripheral conductive housing structures 12W). The conductive support plate may form an exterior rear surface of device 10 or may be covered by a dielectric cover layer such as a thin cosmetic layer, protective coating, and/or other coatings that may include dielectric materials such as glass, ceramic, plastic, or other structures that form the exterior surfaces of device 10 and/or serve to hide the conductive support plate from view of the user (e.g., the conductive support plate may form part of rear housing wall 12R). Device 10 may also include conductive structures such as printed circuit boards, components mounted on printed circuit boards, and other internal conductive structures. These conductive structures, which may be used in forming a ground plane in device 10, may extend under active area AA of display 14, for example.

In regions 22 and 20, openings may be formed within the conductive structures of device 10 (e.g., between peripheral conductive housing structures 12W and opposing conductive ground structures such as conductive portions of rear housing wall 12R, conductive traces on a printed circuit board, conductive electrical components in display 14, etc.). These openings, which may sometimes be referred to as gaps, may be filled with air, plastic, and/or other dielectrics and may be used in forming slot antenna resonating elements for one or more antennas in device 10, if desired.

Conductive housing structures and other conductive structures in device 10 may serve as a ground plane for the antennas in device 10. The openings in regions 22 and 20 may serve as slots in open or closed slot antennas, may serve as a central dielectric region that is surrounded by a conductive path of materials in a loop antenna, may serve as a space that separates an antenna resonating element such as a strip antenna resonating element or an inverted-F antenna resonating element from the ground plane, may contribute to the performance of a parasitic antenna resonating element, or may otherwise serve as part of antenna structures formed in regions 22 and 20. If desired, the ground plane that is under active area AA of display 14 and/or other metal structures in device 10 may have portions that extend into parts of the ends of device 10 (e.g., the ground may extend towards the dielectric-filled openings in regions 22 and 20), thereby narrowing the slots in regions 22 and 20. Region 22 may sometimes be referred to herein as lower region 22 or lower end 22 of device 10. Region 20 may sometimes be referred to herein as upper region 20 or upper end 20 of device 10.

In general, device 10 may include any suitable number of antennas (e.g., one or more, two or more, three or more, four or more, etc.). The antennas in device 10 may be located at opposing first and second ends of an elongated device housing (e.g., at lower region 22 and/or upper region 20 of device 10 of FIG. 1), along one or more edges of a device housing, in the center of a device housing, in other suitable locations, or in one or more of these locations. The arrangement of FIG. 1 is illustrative and non-limiting.

Portions of peripheral conductive housing structures 12W may be provided with peripheral gap structures. For example, peripheral conductive housing structures 12W may be provided with one or more dielectric-filled gaps such as gaps 18, as shown in FIG. 1. The gaps in peripheral conductive housing structures 12W may be filled with dielectric such as polymer, ceramic, glass, air, other dielectric materials, or combinations of these materials. Gaps 18 may divide peripheral conductive housing structures 12W into one or more peripheral conductive segments. The conductive segments that are formed in this way may form parts of antennas in device 10 if desired. Other dielectric openings may be formed in peripheral conductive housing structures 12W (e.g., dielectric openings other than gaps 18) and may serve as dielectric antenna windows for antennas mounted within the interior of device 10. Antennas within device 10 may be aligned with the dielectric antenna windows for conveying radio-frequency signals through peripheral conductive housing structures 12W. Antennas within device 10 may also be aligned with inactive area IA of display 14 for conveying radio-frequency signals through display 14.

To provide an end user of device 10 with as large of a display as possible (e.g., to maximize an area of the device used for displaying media, running applications, etc.), it may be desirable to increase the amount of area at the front face of device 10 that is covered by active area AA of display 14. Increasing the size of active area AA may reduce the size of inactive area IA within device 10. This may reduce the area behind display 14 that is available for antennas within device 10. For example, active area AA of display 14 may include conductive structures that serve to block radio-frequency signals handled by antennas mounted behind active area AA from radiating through the front face of device 10. It would therefore be desirable to be able to provide antennas that occupy a small amount of space within device 10 (e.g., to allow for as large of a display active area AA as possible) while still allowing the antennas to communicate with wireless equipment external to device 10 with satisfactory efficiency bandwidth.

In a typical scenario, device 10 may have one or more upper antennas and one or more lower antennas. An upper antenna may, for example, be formed in upper region 20 of device 10. A lower antenna may, for example, be formed in lower region 22 of device 10. Additional antennas may be formed along the edges of housing 12 extending between regions 20 and 22 if desired. The antennas may be used separately to cover identical communications bands, overlapping communications bands, or separate communications bands. The antennas may be used to implement an antenna diversity scheme or a multiple-input-multiple-output (MIMO) antenna scheme. Other antennas for covering any other desired frequencies may also be mounted at any desired locations within the interior of device 10. The example of FIG. 1 is illustrative and non-limiting. If desired, housing 12 may have other shapes (e.g., a square shape, cylindrical shape, spherical shape, combinations of these and/or different shapes, etc.).

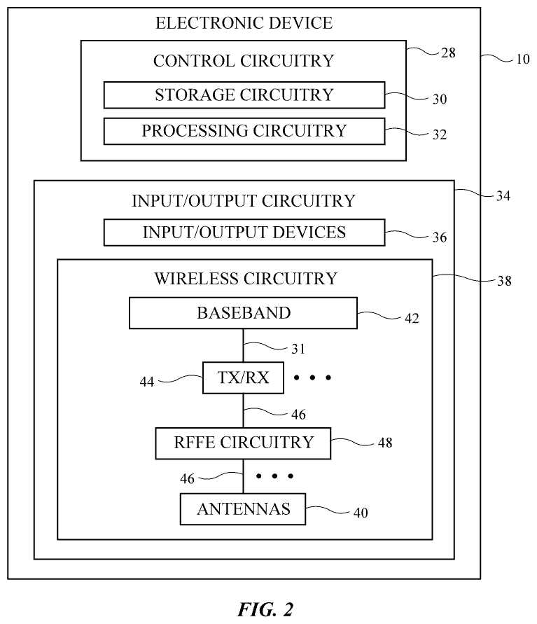

A schematic diagram of illustrative components that may be used in device 10 is shown in FIG. 2. As shown in FIG. 2, device 10 may include control circuitry 28. Control circuitry 28 may include storage such as storage circuitry 30. Storage circuitry 30 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 30 may include storage that is integrated within device 10 and/or removable storage media.

Control circuitry 28 may include processing circuitry such as processing circuitry 32. Processing circuitry 32 may be used to control the operation of device 10. Processing circuitry 32 may include on one or more processors such as microprocessors, microcontrollers, digital signal processors, host processors, baseband processor integrated circuits, application specific integrated circuits, central processing units (CPUs), graphics processing units (GPUs), etc. Control circuitry 28 may be configured to perform operations in device 10 using hardware (e.g., dedicated hardware or circuitry), firmware, and/or software. Software code for performing operations in device 10 may be stored on storage circuitry 30 (e.g., storage circuitry 30 may include non-transitory (tangible) computer readable storage media that stores the software code). The software code may sometimes be referred to as program instructions, software, data, instructions, or code. Software code stored on storage circuitry 30 may be executed by processing circuitry 32.

Control circuitry 28 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 28 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband (UWB) protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol (e.g., a WLAN RAT, a WPAN RAT, a cellular telephone RAT such as a 4G RAT, 5G RAT, 3G RAT, 6G RAT, etc., a UWB RAT, etc.).

Device 10 may include input-output circuitry 34. Input-output circuitry 34 may include input-output devices 36. Input-output devices 36 may be used to allow data to be supplied to device 10 and to allow data to be provided from device 10 to external devices. Input-output devices 36 may include user interface devices, data port devices, and other input-output components. For example, input-output devices 36 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 36 may be peripherals that are coupled to a main processing unit or other portion of device 10 via a wired or wireless link).

Input-output circuitry 34 may include wireless circuitry 38 to support wireless communications. Wireless circuitry 38 (sometimes referred to herein as wireless communications circuitry 38) may include baseband circuitry such as baseband circuitry 42 (e.g., one or more baseband processors and/or other circuitry that operates at baseband), radio-frequency (RF) transceiver circuitry such as one or more transceivers (TX/RX) 44, radio-frequency front end (RFFE) circuitry such as RFFE circuitry 48, and one or more antennas 40. If desired, wireless circuitry 38 may include multiple antennas 40 that are arranged into a phased antenna array (sometimes referred to as a phased array antenna) that conveys radio-frequency signals within a corresponding signal beam that can be steered in different directions.

Baseband circuitry 42 may be coupled to transceiver(s) 44 over one or more baseband signal paths 31. Baseband circuitry 42 may include, for example, modulators (encoders) and demodulators (decoders) that operate on baseband signals. Transceiver(s) 44 may sometimes also be referred to herein as radio(s) 44. Each transceiver 44 may be coupled to one or more antennas 40 over one or more radio-frequency transmission line paths 46 (sometimes referred to herein as radio-frequency signal paths 46). RFFE circuitry 48 may be disposed on one or more radio-frequency transmission line paths 46 between one or more transceivers 44 and one or more antennas 40.

Each transceiver 44 may include a transmitter and/or receiver that transmits and/or receives radio-frequency signals. Each transceiver 44 may convey radio-frequency signals using one or more corresponding RATs. If desired, different transceivers 44 may convey radio-frequency signals using different RATs (e.g., a first transceiver 44 may convey cellular telephone signals, a second transceiver 44 may convey Wi-Fi signals, etc.). If desired, the same transceiver 44 may convey radio-frequency signals using two or more RATs (e.g., a given transceiver 44 may convey both Wi-Fi and Bluetooth signals, a given transceiver 44 may convey both 4G cellular telephone signals and 5G cellular telephone signals, a given transceiver 44 may both convey cellular telephone signals and receive satellite navigation signals, etc.).

Each transceiver 44 may be coupled to the same antenna 40 over different radio-frequency transmission line paths 46, two or more transceivers 44 may be coupled to the same antenna 40 over the same radio-frequency transmission line path, a given transceiver 44 may be coupled to different antennas over different radio-frequency transmission line paths, etc. In general, any desired number of one or more radio-frequency transmission line paths 46 may be used to couple one or more transceivers 44 to one or more antennas 40 and, if desired, two or more transceivers 44 may be coupled to the same antenna(s) 40 over the same radio-frequency transmission line path(s) 46. Any desired number of two or more of the transceivers 44 in wireless circuitry 38 may be coupled to the same RFFE circuitry 48 (e.g., RFFE circuitry 48 disposed on the one or more radio-frequency transmission line paths 46 coupling the two or more transceivers 44 to one or more antennas 40) or different respective transceivers 44 may be coupled to different respective RFFE circuitry 48. In general, wireless circuitry 38 may include any desired number of transceivers 44, any desired number of radio-frequency transmission line paths 46, and any desired number of antennas 40.

Radio-frequency transmission line path(s) 46 may be coupled to antenna feeds on one or more antennas 40. Each antenna feed may, for example, include a positive antenna feed terminal and a ground antenna feed terminal. Each radio-frequency transmission line path 46 may have a positive transmission line signal path that is coupled to one or more positive antenna feed terminals and may have a ground transmission line signal path that is coupled to the ground antenna feed terminal. This example is merely illustrative and, in general, antennas 40 may be fed using any desired antenna feeding scheme.

Each radio-frequency transmission line path 46 may include one or more radio-frequency transmission lines that are used to route radio-frequency signals within device 10. Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Radio-frequency transmission line paths 46 may also include radio-frequency connectors that couple multiple transmission lines together. Transmission lines in device 10 such as transmission lines in a radio-frequency transmission line path 46 may be integrated into rigid and/or flexible printed circuit boards. In some implementations, radio-frequency transmission line paths such as radio-frequency transmission line path 46 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

In performing wireless transmission, baseband circuitry 42 may provide baseband signals to a transceiver 44 over baseband signal path(s) 31. Transceiver 44 (e.g., one or more transmitters in transceiver 44) may include circuitry for converting the baseband signals received from baseband circuitry 42 into corresponding radio-frequency signals. For example, transceiver 44 may include mixer circuitry for up-converting the baseband signals to radio frequencies prior to transmission over antenna(s) 40. Transceiver 44 may also include digital to analog converter (DAC) and/or analog to digital converter (ADC) circuitry for converting signals between digital and analog domains. Transceiver 44 may transmit the radio-frequency signals over antenna(s) 40 via one or more radio-frequency transmission line paths 46 and RFFE circuitry 48. Antenna(s) 40 may transmit the radio-frequency signals to external wireless equipment (e.g., a wireless access point, a wireless base station, another device 10, an accessory device, a peripheral device, a head-mounted device, a communications satellite, etc.) by radiating the radio-frequency signals into free space.

In performing wireless reception, antenna(s) 40 may receive radio-frequency signals from the external wireless equipment. The received radio-frequency signals may be conveyed to a corresponding transceiver 44 via radio-frequency transmission line path(s) 46 and RFFE circuitry 48. Transceiver 44 may include circuitry for converting the received radio-frequency signals into corresponding baseband signals. For example, transceiver 44 may include one or more receivers having mixer circuitry for down-converting the received radio-frequency signals to baseband frequencies prior to conveying the baseband signals to baseband circuitry 42.

RFFE circuitry 48 may include radio-frequency front end components that operate on radio-frequency signals conveyed over the corresponding radio-frequency transmission line path(s) 46. RFFE circuitry 48 may include one or more RFFE modules. Each RFFE module may include corresponding radio-frequency components for operating on radio-frequency signals within a corresponding set of one or more frequency bands and/or for a corresponding set of one or more antennas 40. RFFE circuitry 48 may sometimes also be referred to herein simply as radio-frequency front end 48.

Each RFFE module in RFFE circuitry 48 may include corresponding radio-frequency components mounted a different respective substrate such as a printed circuit board substrate (e.g., a rigid or flexible printed circuit board). If desired, one or more of the RFFE modules may be a multi-chip module (MCM). The radio-frequency components of each RFFE module may be formed from one or more integrated circuits and/or surface mount components (e.g., surface mount technology (SMT) components) mounted (e.g., soldered) to the corresponding substrate of that RFFE module, may be printed onto the substrate, may be embedded within the substrate, etc. Each RFFE module may include respective control circuitry, a respective control interface, a respective power interface (e.g., power supply pins), respective I/O pins, a respective digital interface, etc.

The radio-frequency front end components in each RFFE module of RFFE circuitry 48 may include switching circuitry (e.g., one or more radio-frequency switches), radio-frequency filter circuitry (e.g., low pass filters, high pass filters, notch filters, band pass filters, multiplexing circuitry, duplexer circuitry, diplexer circuitry, triplexer circuitry, switchplexer circuitry, etc.), impedance matching circuitry (e.g., circuitry that helps to match the impedance of antenna(s) 40 to the impedance of radio-frequency transmission line path(s) 46, circuitry that helps to match the impedance of some components in RFFE circuitry 48 to other components in RFFE circuitry 48, etc.), antenna tuning circuitry (e.g., networks of capacitors, resistors, inductors, and/or switches that adjust the frequency response of antennas 40), radio-frequency amplifier circuitry (e.g., power amplifier (PA) circuitry such as one or more power amplifiers and/or low-noise amplifier (LNA) circuitry such as one or more low noise amplifiers), radio-frequency (RF) coupler circuitry, power detector (PD) circuitry such as one or more power detectors 38, charge pump circuitry, power management circuitry, low dropout (LDO) regulator circuitry, digital control and interface circuitry, and/or any other desired circuitry that operates on the radio-frequency signals transmitted and/or received by the antenna(s) 40 coupled to RFFE circuitry 48 over the corresponding radio-frequency transmission line path(s) 46.

While control circuitry 28 is shown separately from wireless circuitry 38 in the example of FIG. 2 for the sake of clarity, wireless circuitry 38 may include processing circuitry that forms a part of processing circuitry 32 and/or storage circuitry that forms a part of storage circuitry 30 of control circuitry 28 (e.g., portions of control circuitry 28 may be implemented on wireless circuitry 38). As an example, baseband circuitry 42 and/or portions of transceiver(s) 44(e.g., a host processor on transceiver(s) 44) may form a part of control circuitry 28.

Wireless circuitry 38 may transmit and/or receive wireless signals within corresponding frequency bands of the electromagnetic spectrum (sometimes referred to herein as communications bands or simply as “bands”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone communications bands such as a cellular low band (LB) (e.g., a band between about 600 to 960 MHz), a cellular low-midband (LMB) (e.g., a band between about 1400 to 1550 MHz), a cellular midband (MB) (e.g., a band between about 1700 to 2200 MHz), a cellular high band (HB) (e.g., a band between 2300 to 2700 MHz), a cellular ultra-high band (UHB) (e.g., a band from 3300 to 5000 MHz, or other cellular communications bands between about 600 MHz and about 5000 MHz), 3G bands, 4G LTE bands, 5G New Radio Frequency Range 1 (FR1) bands below 10 GHz, 5G New Radio Frequency Range 2 (FR2) bands between 20 and 60 GHz, other centimeter or millimeter wave frequency bands between 10-100 GHz, near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, ultra-wideband (UWB) frequency bands that operate under the IEEE 802.15.4 protocol and/or other ultra-wideband communications protocols (e.g., a first UWB communications band at 6.5 GHz and/or a second UWB communications band at 8.0 GHz), communications bands under the family of 3GPP wireless communications standards, communications bands under the IEEE 802.XX family of standards, satellite communications bands such as an L-band, S-band (e.g., from 2-4 GHz), C-band (e.g., from 4-8 GHz), X-band, Ku-band (e.g., from 12-18 GHz), Ka-band (e.g., from 26-40 GHz), etc., industrial, scientific, and medical (ISM) bands such as an ISM band between around 900 MHz and 950 MHz or other ISM bands below or above 1 GHz, one or more unlicensed bands, one or more bands reserved for emergency and/or public services, and/or any other desired frequency bands of interest. Each radio 28 may transmit and/or receive radio-frequency signals in one or more of these frequency bands.

Antennas 40 may be formed using any desired antenna structures. For example, antennas 40 may include antennas with resonating elements that are formed from loop antenna structures, patch antenna structures, inverted-F antenna structures, slot antenna structures, planar inverted-F antenna structures, helical antenna structures, monopole antennas, dipoles, hybrids of these designs, etc. Parasitic elements may be included in antennas 40 to adjust antenna performance.

Filter circuitry, switching circuitry, impedance matching circuitry, and other circuitry may be interposed within radio-frequency transmission line path(s) 46, may be incorporated into RFFE circuitry 48, and/or may be incorporated into antenna(s) 40 (e.g., to support antenna tuning, to support operation in desired frequency bands, etc.). These components, sometimes referred to herein as antenna tuning components, may be adjusted (e.g., using control circuitry 28) to adjust the frequency response and wireless performance of antennas 40 over time.

In general, each transceiver 44 may cover (handle) any suitable communications (frequency) bands of interest. The transceiver may convey radio-frequency signals using antenna(s) 40 (e.g., antenna(s) 40 may convey the radio-frequency signals for the transceiver circuitry). The term “convey radio-frequency signals” as used herein means the transmission and/or reception of the radio-frequency signals (e.g., for performing unidirectional and/or bidirectional wireless communications with external wireless communications equipment). Antennas 40 may transmit the radio-frequency signals by radiating the radio-frequency signals into free space (or to free space through intervening device structures such as a dielectric cover layer). Antennas 40 may additionally or alternatively receive the radio-frequency signals from free space (e.g., through intervening devices structures such as a dielectric cover layer). The transmission and reception of radio-frequency signals by antennas 40 each involve the excitation or resonance of antenna currents on an antenna resonating element in the antenna by the radio-frequency signals within the frequency band(s) of operation of the antennas.

In example where multiple antennas 40 are arranged in a phased antenna array, each antenna 40 may form a respective antenna element of the phased antenna array. Conveying radio-frequency signals using the phased antenna array may allow for greater peak signal gain relative to scenarios where individual antennas 40 are used to convey radio-frequency signals. In satellite navigation system links, cellular telephone links, and other long-range links, radio-frequency signals are typically used to convey data over thousands of feet or miles. In Wi-Fi® and Bluetooth® links at 2.4 and 5 GHz and other short-range wireless links, radio-frequency signals are typically used to convey data over tens or hundreds of feet. In scenarios where millimeter or centimeter wave frequencies are used to convey radio-frequency signals, a phased antenna array may convey radio-frequency signals over short distances that travel over a line-of-sight path. To enhance signal reception for millimeter and centimeter wave communications, the phased antenna array may convey radio-frequency signals using beam steering techniques (e.g., schemes in which antenna signal phase and/or magnitude for each antenna in an array are adjusted to perform beam steering).

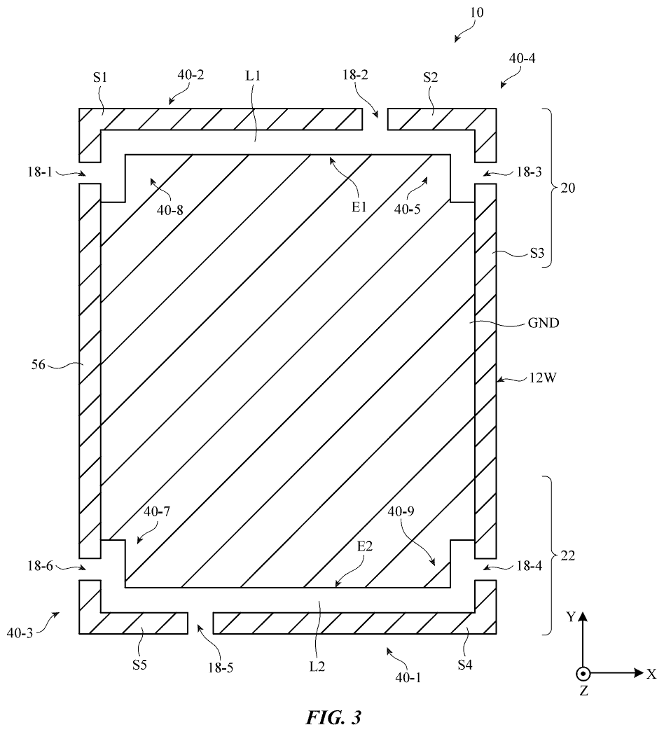

In general, device 10 may include any desired number of antennas. The antennas may be disposed at different locations on device 10. If desired, the antennas may support antenna diversity (e.g., in which different or best-performing antennas are switched into use for covering a particular frequency band at a given time given the current operating conditions of device 10) and/or multiple-input and multiple-output (MIMO) schemes (e.g., in which multiple antennas concurrent transmit or receive wireless data to maximize data throughput). FIG. 3 is a top interior view of device 10 showing how different antennas 40 may be disposed at different locations in device 10.

As shown in FIG. 3, peripheral conductive housing structures 12W of device 10 may include a first conductive sidewall at the left edge of device 10, a second conductive sidewall at the top edge of device 10, a third conductive sidewall at the right edge of device 10, and a fourth conductive sidewall at the bottom edge of device 10 (e.g., in an example where device 10 has a substantially rectangular lateral shape). Peripheral conductive housing structures 12W may be segmented by dielectric-filled gaps 18 such as a first gap 18-1, a second gap 18-2, a third gap 18-3, a fourth gap 18-4, a fifth gap 18-5, and a sixth gap 18-6. Gaps 18-1, 18-2, 18-3, 18-4, 18-5, and 18-6 may be filled with plastic, ceramic, sapphire, glass, epoxy, or other dielectric materials. The dielectric material in the gaps may lie flush with peripheral conductive housing structures 12W at the exterior surface of device 10 if desired. Peripheral conductive housing structures 12W may include additional gaps 18 or fewer than six gaps 18 if desired.

Gap 18-1 may divide the first conductive sidewall to separate segment S6 of peripheral conductive housing structures 12W from segment S1 of peripheral conductive housing structures 12W. Gap 18-2 may divide the second conductive sidewall to separate segment S1 from segment S2 of peripheral conductive housing structures 12W. Gap 18-3 may divide the third conductive sidewall to separate segment S2 from segment S3 of peripheral conductive housing structures 12W. Gap 18-4 may divide the third conductive sidewall to separate segment S3 from segment S4 of peripheral conductive housing structures 12W. Gap 18-5 may divide the fourth conductive sidewall to separate segment S4 from segment S5 of peripheral conductive housing structures 12W. Gap 18-6 may divide the first conductive sidewall to separate segment S5 from segment S6.

In this example, segment S1 forms the top-left corner of device 10 (e.g., segment S1 may have a bend at the corner) and is formed from the first and second conductive sidewalls of peripheral conductive housing structures 12W (e.g., in upper region 20 of device 10). Segment S2 forms the top-right corner of device 10 (e.g., segment S2 may have a bend at the corner) and is formed from the second and third conductive sidewalls of peripheral conductive housing structures 12W (e.g., in upper region 20 of device 10). Segment S4 forms the bottom-right corner of device 10 and is formed from the third and fourth conductive sidewalls of peripheral conductive housing structures 12W (e.g., in lower region 22 of device 10). Segment S5 forms the bottom-left corner of device 10 and is formed from the fourth and first conductive sidewalls of peripheral conductive housing structures 12W (e.g., in lower region 22 of device 10).

Ground structures GND may extend between opposing sidewalls of peripheral conductive housing structures 12W. For example, ground structures GND may extend from segment S6 to segment S3 of peripheral conductive housing structures 12W (e.g., across the width of device 10, parallel to the X-axis). Ground structures GND may include one or more conductive layers such as a conductive support plate running along a dielectric (e.g., glass) cover layer that forms rear housing wall 12R of device 10 (FIG. 1), conductive portions of display 14 (FIG. 1) of device 10 opposite the rear wall, and/or a conductive mid-chassis that is vertically interposed between display 14 and the conductive support plate. The conductive support plate may be replaced by a conductive lower chassis that is not coupled to the dielectric cover layer if desired. Two or more of these structures may be formed from the same integral piece of metal as segments S6 and S3 of peripheral conductive housing structures 12W if desired. Conductive interconnect structures (e.g., conductive springs, conductive clips, conductive foam, conductive adhesive, conductive pins, conductive screws, conductive brackets, conductive tabs, solder, welds, etc.) may couple each of these structures together to form ground structures GND. Ground structures GND may be held at a ground potential or other reference potential and may form part of the antenna ground for the antennas 40 in device 10.

As shown in FIG. 3, device 10 may include multiple slots L between ground structures GND and peripheral conductive housing structures 12W. For example, device 10 may include an upper slot such as slot L1 in upper region 20 and a lower slot such as slot L2 in lower region 22. The lower edge of slot L1 may be defined by upper edge E1 of ground structures GND. The upper edge of slot L1 may be defined by segments S1 and S2 (e.g., slot L1 may be interposed between ground structures GND and segments S1 and S2 of peripheral conductive housing structures 12W). The upper edge of slot L2 may be defined by lower edge E2 of ground structures GND. The lower edge of slot L2 may be defined by segments S5 and S4 (e.g., slot L2 may be interposed between ground structures GND and segments S5 and S4 of peripheral conductive housing structures 12W).

Slot L1 may have an elongated shape extending from a first end at gap 18-2 to an opposing second end at gap 18-3 (e.g., slot L1 may span the width of device 10). Similarly, slot L2 may have an elongated shape extending from a first end at gap 18-6 to an opposing second end at gap 18-4 (e.g., slot L2 may span the width of device 10). Slots L1 and L2 may be filled with air, plastic, glass, sapphire, epoxy, ceramic, or other dielectric material. Slot L1 may be continuous with gaps 18-1, 18-2, and 18-3 in peripheral conductive housing structures 12W if desired (e.g., a single piece of dielectric material may be used to fill both slot L1 and gaps 18-1, 18-2, and 18-3). Similarly, slot L2 may be continuous with gaps 18-6, 18-5, and 18-4 if desired (e.g., a single piece of dielectric material may be used to fill both slot L2 and gaps 18-6, 18-5, and 18-4).

In implementations that are described herein as an example, device 10 may include at least nine antennas 40 at different locations on device 10 such as at least antennas 40-1, 40-2, 40-3, 40-4, 40-5, 40-6, 40-7, 40-8, and 40-9. This is illustrative and non-limiting. In general, device 10 may include any desired number of antennas 40 (e.g., more than nine antennas or fewer than nine antennas). Ground structures GND, segment S1, segment S2, and portions of slot L1 may be used in forming multiple antennas 40 in upper region 20 of device 10 (sometimes referred to herein as upper antennas) such as antennas 40-2, 40-4, 40-8, and/or 40-5. As one example, antenna 40-2 may have a resonating element arm formed from segment S1 and an antenna feed coupled between segment S1 and ground structures GND, antenna 40-4 may have a resonating element arm formed from segment S2 and an antenna feed coupled between segment S2 and ground structures GND, antenna 40-8 may have an antenna resonating element formed from a portion of slot L1 (e.g., between segment S6 and ground structures GND) or from conductive traces on a flexible printed circuit overlapping or adjacent the volume of antenna 40-2, and antenna 40-5 may have an antenna resonating element formed from a portion of slot L1 (e.g., between segment S3 and ground structures GND) or from conductive traces on a flexible printed circuit overlapping or adjacent the volume of antenna 40-4.

On the other hand, ground structures GND, portions of slot L2, segment S5, and segment S4 may be used in forming multiple antennas 40 in lower region 22 of device 10 (sometimes referred to herein as lower antennas) such as antennas 40-1, 40-3, 40-7, and 40-9. As one example, antenna 40-3 may have a resonating element arm formed from segment S5 and an antenna feed coupled between segment S5 and ground structures GND, antenna 40-1 may have a resonating element arm formed from segment S4 and an antenna feed coupled between segment S4 and ground structures GND, antenna 40-7 may have an antenna resonating element formed from a portion of slot L2 (e.g., between segment S6 and ground structures GND) or from conductive traces on a flexible printed circuit overlapping or adjacent the volume of antenna 40-3, and antenna 40-9 may have an antenna resonating element formed from a portion of slot L2 (e.g., between segment S3 and ground structures GND) or from conductive traces on a flexible printed circuit overlapping or adjacent the volume of antenna 40-1.

This example is illustrative and non-limiting. If desired, one or more of these antennas or other antennas 40 may be located between regions 20 and 22. Region 20 may include any desired number of zero, one, or more than one antenna 40. Region 22 may include any desired number of zero, one, or more than one antenna 40. If desired, one or more phased antenna arrays for conveying millimeter and centimeter wave signals may at least partially overlap slot L1, ground structures GND, and/or slot L2 (not shown in FIG. 3 for the sake of clarity). The phased antenna arrays may radiate through display 14 (FIG. 1), through rear housing wall 12R (FIG. 1), and/or through one or more apertures in peripheral conductive housing structures 12W. Device 10 may have other form factors (e.g., a non-rectangular housing having any desired number of straight and/or curved sides).

Each of antennas 40-1 through 40-9 may convey radio-frequency signals in different combinations of one or more frequency bands. For example, antennas 40-1 through 40-9 may collectively convey radio-frequency signals in different combinations of frequency bands including WLAN bands, WPAN bands, satellite navigation bands, and cellular bands such as one or more cellular low bands LB, cellular low-midbands LMB, cellular midbands MB, cellular high bands HB, cellular ultra-high bands UHB, etc. Different ones of antennas 40-1 through 40-9 may cover any desired combination of one or more of these bands.

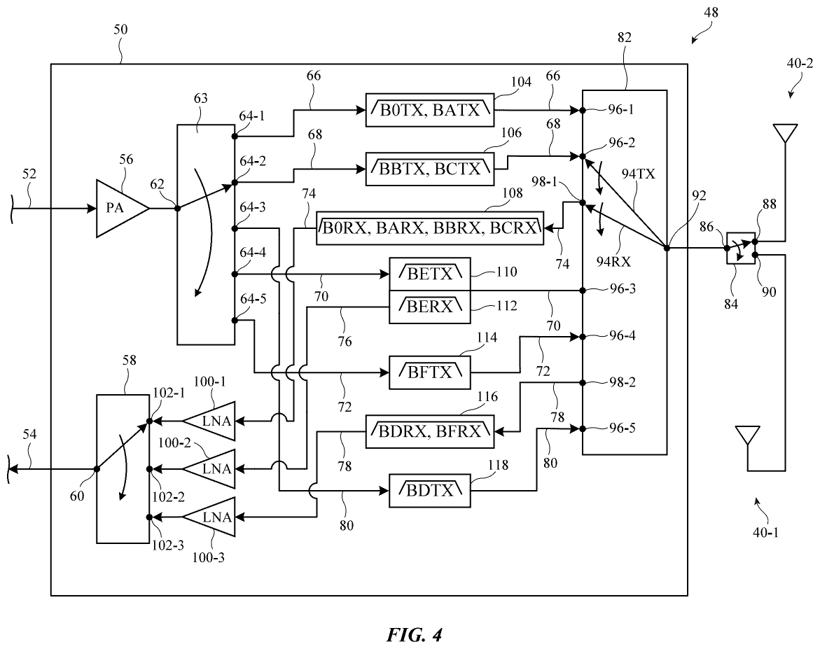

One or more of the antennas 40 in device 10 such as antenna 40-2 and/or antenna 40-1 may convey radio-frequency signals in multiple frequency bands. The antenna and the transceiver may be switched between different frequency bands over time (e.g., depending on the communications resources assigned to device 10 by the corresponding communications network). Care should be taken to ensure that the antenna is able to convey radio-frequency signals across these different frequency bands with satisfactory levels of isolation and wireless performance, while also minimizing the space and/or power consumed by the wireless circuitry. To configure the antenna to convey radio-frequency signals across these different frequency bands with satisfactory levels of wireless performance and while minimizing the space and/or power consumed by the wireless circuitry 24, the RFFE circuitry 48 (FIG. 2) coupled between transceiver 44 and the antenna may implement a combined and switched filter architecture (e.g., may include circuitry that performs switched filter combining). FIG. 4 is a circuit diagram showing one example of how RFFE circuitry 48 may have a combined and switched filter architecture for performing switched filter combining for one or more corresponding antennas.

As shown in FIG. 4, RFFE circuitry 48 may include a RFFE module such as RFFE module 50 (e.g., an amplifier or PA module such as a switched power amplifier duplexer module). Module 50 may couple one or more transceivers 44 (FIG. 2) to one or more antennas such as antenna 40-1 and/or antenna 40-2 (e.g., located at ends 20 and 22 as shown in FIG. 3). This is illustrative and non-limiting. In general, RFFE module 50 may couple the transceiver(s) to only one of antennas 40-1 or 40-2, to any of antennas 40-1 through 40-9 of FIG. 4, or to any desired combination of one or more of antennas 40-1 through 40-9 and/or other antennas in device 10.

Module 50 may be disposed on the radio-frequency transmission line path(s) 46 (FIG. 2) between transceiver(s) 44 and antenna(s) 40. The radio-frequency transmission line path(s) 46 may include a transmit signal path 52 coupled to one or more transmit ports of the transceiver(s) and may include a receive signal path 54 coupled to one or more receive ports of the transceiver(s). Module 50 may have amplifier circuitry, switching circuitry, filter circuitry, and/or other front end circuitry disposed on a common (shared) substrate. The substrate may be a rigid or flexible printed circuit, an integrated circuit (IC) substrate (e.g., a semiconductor substrate), an IC package substrate, or another substrate. Module 50 may convey radio-frequency signals between the transceiver(s) and the antenna(s) in a set of different frequency bands.

As shown in FIG. 4, module 50 may include radio-frequency amplifier circuitry such as power amplifier (PA) 56 and one or more low noise amplifiers (LNAs) 100. Module 50 may include different LNAs 100 for conveying radio-frequency signals in different frequency bands. Module 50 may include, for example, at least a first LNA 100-1, a second LNA 100-2, and a third LNA 100-3. Module 50 may include radio-frequency switching circuitry such as a transmit switch 63 (sometimes also referred to as PA switch 63, PA band selection switch 63, or transmit band selection switch 63), an antenna switch 82 (sometimes also referred to as antenna selection switch 82 or transmit/receive switch 82), and a receive switch 58 (sometimes also referred to as LNA switch 58, LNA band selection 58, or receive band selection switch 58).

Module 50 may include radio-frequency signal paths such as signal paths 66, 68, 74, 70, 76, 72, 78, and 80. Signal paths 66, 68, 74, 70, 76, 72, 78, and 80 may include radio-frequency transmission line segments and/or traces, for example. Module 50 may include filter circuitry disposed on the signal paths. For example, module 50 may include filters 104, 106, 108, 110, 112, 114, 116, and 118 disposed on the signal paths.

The input of PA 56 may be coupled to transmit signal path 52. The output of PA 56 may be coupled to input terminal 62 of transmit switch 63. Transmit switch 63 may have a set of output terminals 64 such as output terminals 64-1, 64-2, 64-3, 64-4, and 64-5. Antenna switch 82 may have a set of transmit terminals 96 that are used to transmit signals over the antenna(s). For example, antenna switch 82 may have transmit terminals 96-1, 96-2, 96-3, 96-4, and 96-5. Antenna switch 82 may also have a set of receive terminals 98 such as receive terminals 98-1 and 98-2. While referred to herein as a transmit terminal, transmit terminal 96-3 may also form a receive terminal 98 of antenna switch 82 and is therefore sometimes referred to herein simply as terminal 96-3. Finally, antenna switch 82 may have an antenna terminal 92 communicably coupled to one or more antennas such as antennas 40-1 and 40-2. Antenna terminal 92 may form an input terminal of antenna switch 82 during signal reception and may form an output terminal of antenna switch 82 during signal transmission.

Receive switch 58 may have a set of input terminals 102 such as input terminals 102-1, 102-2, and 102-3. Receive switch 58 may have an output terminal 60 coupled to receive signal path 54. Antenna selection switch 84 may have a terminal 88 coupled to antenna 40-2 and may have a terminal 90 coupled to antenna 40-1. Antenna selection switch 84 may be disposed in module 50 or may be separate from module 50. Alternatively, antenna selection switch 84 may be integrated into antenna switch 82 (e.g., antenna switch 82 may have a first antenna terminal 92 coupled to antenna 40-2 and a second antenna terminal 92 coupled to antenna 40-1). Alternatively, antenna selection switch 84 may be omitted and antenna terminal 92 may be coupled to only a single antenna 40.

The terminals of switches 63, 82, 84, and 58 are sometimes also referred to herein as ports of the switches. The example of FIG. 4 is illustrative and non-limiting. In general, there may be other numbers of output terminals 64 on transmit switch 63, input terminals 102 on receive switch 58, and terminals 96 and 98 on antenna switch 82 (e.g., the number of output terminals 64 on transmit switch 63, input terminals 102 on receive switch 58, and terminals 96 and 98 on antenna switch 82 may depend on the number of radio-frequency frequency bands handled by module 50 (e.g., PA 56)). In general, antenna switch 82 and/or antenna selection switch 84 may couple module 50 to any desired number of antennas 40.

Signal path 66 may couple output terminal 64-1 of transmit switch 63 to transmit terminal 96-1 of antenna switch 82. Signal path 68 may couple output terminal 64-2 of transmit switch 63 to transmit terminal 96-2 of antenna switch 82. Signal path 80 may couple output terminal 64-3 of transmit switch 63 to transmit terminal 96-5 of antenna switch 82. Signal path 70 may couple output terminal 64-4 of transmit switch 63 to transmit terminal 96-3 of antenna switch 82. Signal path 72 may couple output terminal 64-5 of transmit switch 63 to transmit terminal 96-4 of antenna switch 82. Signal paths 66, 68, 80, 70, and 72 may be used in the transmission of radio-frequency signals from PA 56 to antenna(s) 40 and are therefore sometimes also referred to herein as transmit signal paths or transmit paths.

Signal path 76 may couple signal path 70 and transmit terminal 96-3 of antenna switch 82 to the input of LNA 100-2. Signal path 74 may couple receive terminal 98-1 of antenna switch 82 to the input of LNA 100-1. Signal path 78 may couple receive terminal 98-2 of antenna switch 82 to the input of LNA 100-3. Signal paths 76, 74, and 78 may be used in the reception of radio-frequency signals by the antenna(s) 40 and are therefore sometimes also referred to herein as receive signal paths or receive paths. The output of LNA 100-1 may be coupled to input terminal 102-1 of receive switch 58. The output of LNA 100-2 may be coupled to input terminal 102-2 of receive switch 58. The output of LNA 100-3 may be coupled to input terminal 102-3 of receive switch 58.

Filter 104 may be disposed or interposed on signal path 66 between transmit switch 63 and antenna switch 82. Filter 106 may be interposed on signal path 68 between transmit switch 63 and antenna switch 82. Filter 108 may be r interposed on signal path 74 between antenna switch 82 and LNA 100-1. Filter 110 may be interposed on signal path 70 between transmit switch 63 and antenna switch 82. Filter 112 may be coupled between terminal 96-3 (signal path 70) and signal path 76. Filter 114 may be disposed or interposed on signal path 72 between transmit switch 63 and antenna switch 82. Filter 116 may be interposed on signal path 78 between antenna switch 82 and LNA 100-3. Filter 118 may be interposed on signal path 80 between transmit switch 63 and antenna switch 82. Filters 104-118 may each be bandpass filters having different respective passbands, for example. This is illustrative and non-limiting. In general, filters 104-118 may include low pass filters, notch filters, band stop filters, high pass filters, and/or other types of filters. Filters 110 and 112 may be implemented as separate filters having different respective passbands or may be integrated into a single filter having a single passband. Filters 104, 106, 110, 114, and 118 are used to filter radio-frequency signals transmitted by PA 56 and are therefore sometimes also referred to herein as transmit filters. Filters 108, 112, and 116 are used to filter radio-frequency signals received by antenna(s) 40 and are therefore sometimes also referred to herein as receive filters.

The radio-frequency signals conveyed between transceiver(s) 44 and antenna(s) 40 through module 50 may be conveyed in a set of frequency bands. Each frequency band spans a respective range of frequencies. Each frequency band has a corresponding transmit band and a corresponding receive band. The transmit band of a frequency band includes a first subset or sub-range of frequencies from the frequencies spanned by that frequency band. The receive band of a frequency band includes a second subset or sub-range of frequencies from the frequencies spanned by that frequency band. The transmit and receive bands are therefore sometimes also referred to herein as sub-bands of the frequency band. The frequency bands are sometimes also referred to herein as frequency channels or communications bands.

The set of frequency bands handled by module 50 may include any desired number of frequency bands spanning any desired frequencies. In the example of FIG. 4, the set of frequency bands includes a first frequency band B0 spanning a first range of frequencies, a second frequency band BA spanning a second range of frequencies, a third frequency band BB spanning a third range of frequencies, a fourth frequency band BC spanning a fourth range of frequencies, a fifth frequency band BD spanning a fifth range of frequencies, a sixth frequency band BD spanning a sixth range of frequencies, and a seventh frequency band spanning a seventh range of frequencies.

Frequency band B0 may have a corresponding transmit band B0TX and a corresponding receive band B0RX. Frequency band BA may have a corresponding transmit band BATX and a corresponding receive band BARX. Frequency band BB may have a corresponding transmit band BBTX and a corresponding receive band BBRX. Frequency band BC may have a corresponding transmit band BCTX and a corresponding receive band BCRX. Frequency band BD may have a corresponding transmit band BDTX and a corresponding receive band BDRX. Frequency band BE may have a corresponding transmit band BETX and a corresponding receive band BERX. Frequency band BF may have a corresponding transmit band BFTX and a corresponding receive band BFRX.

The frequencies spanned by the frequency bands may be dictated by the communications protocol with which the radio-frequency signals are conveyed, for example, (e.g., a cellular telephone communications protocol). In general, frequency bands B0 through BF may span any desired frequencies. In one implementation that is described herein as an example, frequency bands B0 through BF are cellular low bands LB defined by the 3G, 4G, 5G, and/or future cellular telephone communications protocols (e.g., between around 600 MHz and 960 MHz). For example, frequency band B0 may be cellular band n85 (e.g., at frequencies from 698 MHz to 746 MHz), frequency band BA may be cellular band B12 (e.g., at frequencies from 699 MHz to 746 MHz), frequency band BB may be cellular band B13 (e.g., at frequencies from 746 MHz to 787 MHz), frequency band BC may be cellular band B14 (e.g., at frequencies from 758 MHz to 798 MHz), frequency band BD may be cellular band B20 (e.g., at frequencies from 791 MHz to 862 MHz), frequency band BE may be cellular band B28A (e.g., at frequencies from 703 MHz to 748 MHz), and frequency band BF may be cellular band B28B (e.g., at frequencies from 718 MHz to 803 MHz).

The radio-frequency signals conveyed in frequency bands B0 through BF may be isolated from each other using a combination of switching (e.g., using switches 63, 82, and 58) and filtering (e.g., using filters 104-118). The overlap and/or adjacency of frequency bands B0 through BF may allow a combination of switching and filtering to be performed in such a way so as to minimize the number of filters and the number of LNA's required to achieve suitable levels of isolation and thus suitable levels of wireless performance.

For example, filter 104 may have a passband that overlaps transmit band B0TX and transmit band BATX. Filter 106 may have a passband that overlaps transmit band BBTX and transmit band BCTX. Filter 108 may have a passband that overlaps receive bands B0RX, BARX, BBRX, and BCRX. Filter 110 may have a passband that overlaps transmit band BETX. Filter 112 may have a passband that overlaps receive band BERX. Filter 114 may have a passband that overlaps transmit band BFTX. Filter 116 may have a passband that overlaps receive bands BDRX and BFRX. Filter 118 may have a passband that overlaps receive band BDRX.

During signal transmission, transmit switch 63 may be adjusted to couple input terminal 62 to a selected one of output terminals 64 and thus a selected one of filters 104, 106, 110, 114, or 118 based on the frequency band being used to transmit the radio-frequency signals (e.g., transmit switch 63 may be a single-pole five-throw switch). During signal reception, receive switch 58 may be adjusted to couple output terminal 60 to a selected one of input terminals 102 and thus a selected one of LNAs 100 and filters 108, 112, or 116 based on the frequency band being used to receive the radio-frequency signals (e.g., receive switch 58 may be a single-pole triple-throw switch).

Antenna switch 82 may be a multi-throw switch having a transmit throw 94TX and a receive throw 94RX. Antenna switch 82 may be controlled to adjust transmit throw 94TX to couple antenna terminal 92 to a selected transmit terminal 96 based on the frequency band used to transmit the radio-frequency signals. At the same time, antenna switch 82 may be controlled to adjust receive throw 94RX to couple antenna terminal 92 to a selected receive terminal 98 (or terminal 96-3) based on the frequency band used to receive the radio-frequency signals. In this way, module 50 may be used to concurrently transmit radio-frequency signals and receive radio-frequency signals in a particular frequency band (e.g., the transmit band and the receive band of a given frequency band, respectively). In other words, PA 56, transmit switch 63, a selected transmit filter, and antenna switch 82 may be used to transmit radio-frequency signals in a corresponding frequency band (e.g., a transmit band of the frequency band) from transmit signal path 52 to antenna(s) 40 while antenna switch 82, a selected receive filter and LNA 100, and receive switch 58 are concurrently used to receive radio-frequency signals in the corresponding frequency band (e.g., a receive band of the frequency band). The switches may be adjusted over time as the frequency band of the radio-frequency changes.

For example, as shown in FIG. 4, when module 50 is conveying radio-frequency signals in frequency bands BB or BC, transmit switch 63 may be placed in a switch state in which input terminal 62 is coupled to output terminal 64-2 and thus signal path 68, filter 106, and transmit terminal 96-2 of antenna switch 82. At the same time, receive switch 58 is placed in a switch state in which input terminal 102-1 and thus LNA 100-1, signal path 74, filter 108, and receive terminal 98-1 of antenna switch 82. At the same time, antenna switch 82 is placed in a switch state in which transmit throw 94TX is coupled to transmit terminal 96-2, thereby coupling signal path 68 to the antenna(s), and in which receive throw 94RX is coupled to receive terminal 98-1 and thus signal path 74. Module 50 may then transmit radio-frequency signals in transmit band BBTX or transmit band BCRX via PA 56, transmit switch 64, signal path 68, filter 106, and antenna switch 82. At the same time, module 50 may receive radio-frequency signals in receive band BBRX or receive band BCRX via antenna switch 82, signal path 74, filter 108, LNA 100-1, and receive switch 58. The switches may be dynamically adjusted over time as the frequency band changes.

In some implementations, antenna switch 82 includes only a single throw and each of bands B0-BF is provided with a different respective filter. By sharing a single filter 108 across receive bands B0RX, BARX, BBRX, and BCRX, a single filter 106 across transmit bands BBTX and BCTX, a single filter 104 across transmit bands B0TX and BATX, and a single filter 116 across receive bands BDRX and BFRX, and by concurrently coupling antenna terminal 92 to a transmit terminal and a receive terminal of antenna switch 82 in this way, the number of filters required to convey radio-frequency signals in frequency bands B0-BF with sufficient levels of isolation may be reduced from ten filters to eight filters and the number of LNAs 100 required to convey radio-frequency signals in frequency bands B0-BF with sufficient isolation may be reduced from five LNAs to three LNAs, thereby minimizing the size and power consumption of module 50. The overlap and/or adjacency of frequency bands B0-BF may allow for these levels of space and power savings, for example.

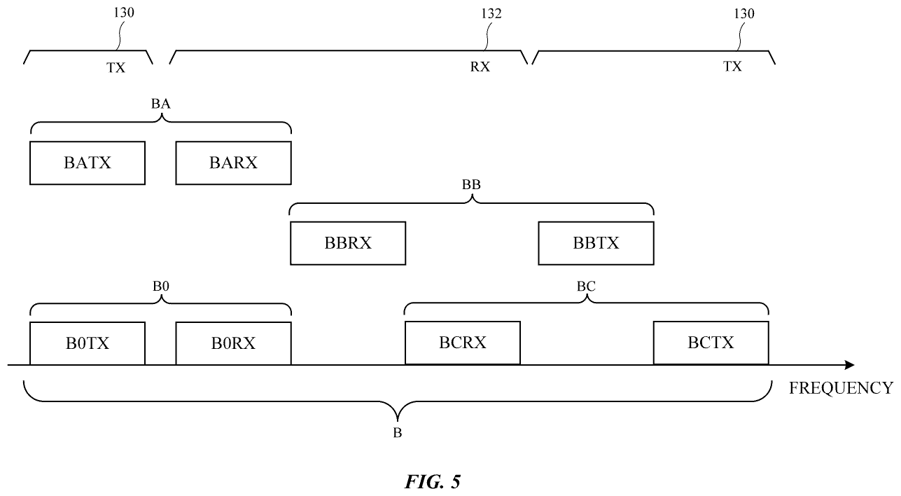

FIG. 5 is a frequency diagram illustrating the passbands of filters 104, 108, and 106. As shown in FIG. 5, frequency band B0 may have a transmit band B0TX (e.g., 700-716 MHz) and a receive band B0RX (e.g., 728-746 MHz) that is higher than transmit band B0TX. Frequency band BA may have a transmit band BATX (e.g., 699-716 MHz) that at least partially overlaps transmit band B0TX and may have a receive band BARX (e.g., 729-746 MHz) that is higher than transmit band BATX and that at least partially overlaps receive band B0RX.

Frequency band BC may have a transmit band BCTX (e.g., 788-798 MHz) and a receive band BCRX (e.g., 758-768 MHz) that is lower than transmit band BCTX. Frequency band BB may have a receive band BBRX (e.g., 746-756 MHz) and may have a transmit band BBTX (e.g., 777-787 MHz) that is higher than receive band BBRX. Receive band BBRX may have a lower edge (frequency) at, aligned with, or adjacent to the upper edge (frequency) of frequency band B0 (e.g., receive band B0RX) and/or frequency band BA (e.g., receive band BARX). Transmit band BBTX may have an upper edge (frequency) at, aligned with, or adjacent to the lower edge (frequency) of transmit band BCTX and may have a lower edge higher than the upper edge of receive band BCRX. As referred to herein, two frequencies are “adjacent” to each other if the two frequencies are within +/−50 Hz, 40 Hz, 20-50 Hz, 10-50 Hz, 20 Hz, 10 Hz, 5 Hz, 5-50 Hz, or 5-25 Hz of each other.

Filter 104 may have a passband 130. Passband 130 may overlap transmit bands BATX and B0TX (e.g., the lower cutoff frequency of passband 130 may be at or lower than the lower edge of transmit bands BATX and B0TX and the upper cutoff frequency of passband 130 may be at or higher than the upper edge transmit bands BATX and B0TX).

Filter 108 may have a passband 132. Passband 132 may be at higher frequencies than passband 130 (e.g., the lower cutoff frequency of passband 132 may be at or higher than the upper cutoff frequency of passband 130 such that passbands 130 and 132 are non-overlapping). Passband 132 may overlap receive bands BARX, BBRX, BCRX, and B0RX (e.g., the lower cutoff frequency of passband 132 may be at or lower than the lower edge of receive bands BARX, BBRX, and B0RX and the upper cutoff frequency of passband 132 may be at or higher than the upper edge receive bands BBRX and BCRX).

Filter 106 may have a passband 134. Passband 134 may be at higher frequencies than passband 132 (e.g., the lower cutoff frequency of passband 134 may be at or higher than the upper cutoff frequency of passband 132 such that passbands 132 and 134 are non-overlapping). Passband 134 may overlap transmit bands BBTX and BCTX, which are separated in frequency from the other transmit bands by the receive bands of frequency bands BA, BB, B0, and BC (e.g., the lower cutoff frequency of passband 134 may be at or lower than the lower edge of transmit bands BBTX and BCTX and the upper cutoff frequency of passband 134 may be at or higher than the upper edge transmit bands BBTX and BCTX). As shown in FIG. 5, a separate transmit filter needs to be used for frequency bands BA/B0 than for frequency bands BB/BC because the transmit bands of frequency bands BB/BC are separated in frequency from the transmit bands of frequency bands BA/B0 by the receive bands of frequency bands BA, BB, B0, and BC. However, by sharing the filters in this way and combining the filtering with switching by antenna switch 82 may allow module 50 to concurrently convey radio-frequency signals in both the transmit band and the receive band of frequency band BA, frequency band BB, frequency band B0, or frequency band BC at any given time while minimizing the number of LNAs and filters on module 50.

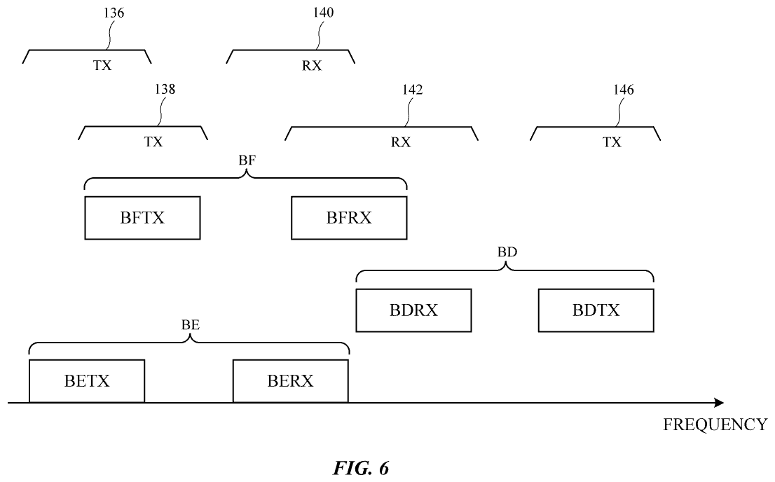

FIG. 6 is a frequency diagram illustrating the passbands of filters 110, 112, 114, 116, and 118. As shown in FIG. 6, frequency band BE may have a transmit band BETX (e.g., 703-733 MHz) and a receive band BERX (e.g., 758-788 MHz) that is higher than transmit band BETX. Frequency band BF may have a transmit band BFTX (e.g., 718-748 MHz) that at least partially overlaps transmit band BETX and may have a receive band BFRX (e.g., 773-803 MHz) that is higher than transmit band BFTX and that at least partially overlaps receive band BERX.

Frequency band BD may have a transmit band BDTX (e.g., 832-862 MHz) and a receive band BDRX (e.g., 791-821 MHz) that is lower than transmit band BDTX and that at least partially overlaps receive band BFRX. Receive band BERX may be higher than transmit band BFTX if desired. Receive band BDRX may be higher than receive band BERX if desired. The upper edge of receive band BDRX may be higher than the upper edge of receive band BFRX and/or the lower edge of receive band BFRX may be lower than the lower edge of receive band BDRX. The lower edge of transmit band BFTX may be higher than the lower edge of transmit band BETX and/or the upper edge of transmit band BFTX may be higher than the upper edge of transmit band BETX. These examples are illustrative and non-limiting and, in general, any two bands described herein as overlapping may be replaced with a first band having a lower edge that is adjacent to the upper edge of a second band or with a first band having an upper edge that is adjacent to the lower edge of a second band.

Filter 110 may have a passband 136. Passband 136 may overlap transmit band BETX (e.g., the lower cutoff frequency of passband 136 may be at or lower than the lower edge of transmit band BETX and the upper cutoff frequency of passband 136 may be at or higher than the upper edge transmit band BETX).

Filter 114 may have a passband 138. Passband 138 may partially overlap passband 136 and/or may include higher frequencies than passband 136. Passband 138 may overlap transmit band BFTX (e.g., the lower cutoff frequency of passband 138 may be at or lower than the lower edge of transmit band BFTX and the upper cutoff frequency of passband 138 may be at or higher than the upper edge of transmit band BFTX).

Filter 112 may have a passband 140. Filter 116 may have passband 142. Passband 140 may partially overlap passband 142 and/or may include lower frequencies than passband 142 (e.g., the lower cutoff frequency of passband 142 may be lower than the upper cutoff frequency of passband 140 and the upper cutoff frequency of passband 142 may be higher than the upper cutoff frequency of passband 140). Passband 40 may overlap receive band BERX. Passband 142 may overlap receive bands BFRX and BDRX.

Filter 118 may have a passband 146. Passband 146 may be higher than passband 142 (e.g., passbands 142 and 146 may be non-overlapping). Passband 146 may overlap transmit band BDTX. If desired, filters 110 and 114 may be replaced with a single filter having a passband that overlaps both transmit bands BETX and BFTX. However, separate filters may exhibit superior emissions than a combined filter.

As shown in FIG. 6, a separate transmit filter needs to be used for frequency band BD than for frequency bands BE and BF because the transmit bands of frequency bands BE/BF are separated in frequency from the transmit band of frequency band BD by the receive bands of frequency bands BD, BE, and BF. The examples of FIGS. 5 and 6 are illustrative and non-limiting and, in general, other bands at other frequencies may be used.

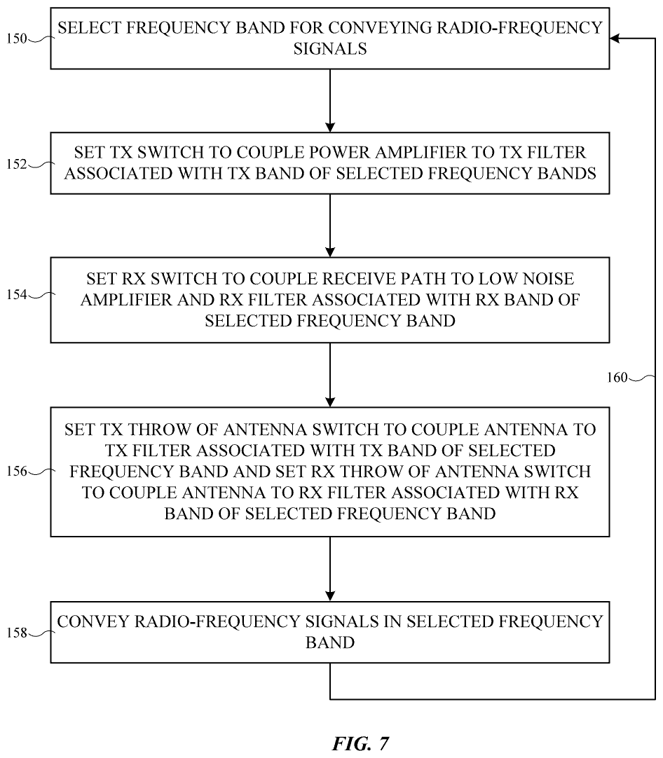

FIG. 7 is a flow chart of illustrative operations involved in using a module 50 to convey radio-frequency signals. At operation 150, transceiver 44 may select (e.g., identify) a frequency band for conveying radio-frequency signals. The frequency band may, for example, be dictated by a communications schedule generated for device 10 by a cellular telephone network, selected by an application running on device 10, selected by the operating system running on device 10, etc. The selected frequency band may have a corresponding transmit (TX) band and receive (RX) band.

At operation 152, control circuitry 28 (FIG. 2) may control transmit switch 63 to couple PA 56 to the transmit filter associated with the selected frequency band (e.g., whichever one of filters 104, 106, 110, 114, and 118 has a passband overlapping the transmit band of the selected frequency band).

At operation 154, control circuitry 28 may control receive switch 58 to couple receive signal path 54 to the LNA 100 and the receive filter associated with the selected frequency band (e.g., whichever of filters 108, 112, and 116 has a passband overlapping the receive band of the selected frequency band).

At operation 156, control circuitry 28 may control transmit throw 94TX of antenna switch 82 to couple the transmit filter associated with the selected frequency band to antenna(s) 40. Control circuitry 28 may also control receive throw 94RX of antenna switch 82 to couple the receive filter associated with the selected frequency band to antenna(s) 40.

At operation 158, module 50 may convey radio-frequency signals in the selected frequency band. The radio-frequency signals in the transmit band of the selected frequency band may be passed from PA 56 through transmit switch 63, the transmit filter associated with the selected frequency band, and antenna switch 82 to antenna(s) 40. The radio-frequency signals in the receive band of the selected frequency band may be concurrently passed from antenna(s) 40 through antenna switch 82, the receive filter associated with the selected frequency band, and receive switch 58 to receive signal path 54. Processing may loop back to operation 160 as the frequency band changes over time.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Wireless circuitry comprising:
an antenna configured to convey radio-frequency signals in a first frequency band and a second frequency band that is higher than the first frequency band;
a first filter communicably coupled to the antenna and having a first passband overlapping a transmit band of the first frequency band;
a second filter communicably coupled to the antenna and having a second passband overlapping a transmit band of the second frequency band; and
a third filter communicably coupled to the antenna and having a third passband overlapping a receive band of the first frequency band and a receive band of the second frequency band.

2. The wireless circuitry of claim 1, wherein the receive band of the first frequency band is higher than the transmit band of the first frequency band.

3. The wireless circuitry of claim 2, wherein the transmit band of the second frequency band is higher than the receive band of the second frequency band.

4. The wireless circuitry of claim 3, wherein the antenna is configured to convey the radio-frequency signals in a third frequency band, the third passband of the third filter overlaps a receive band of the third frequency band, and the receive band of the third frequency band is lower than the transmit band of the second frequency band.

5. The wireless circuitry of claim 4, wherein the second passband of the second filter overlaps a transmit band of the third frequency band, the transmit band of the third frequency band is higher than the transmit band of the second frequency band, and the third passband of the third filter has an upper cutoff frequency lower than the transmit band of the second frequency band.

6. The wireless circuitry of claim 1, further comprising:
a power amplifier;
a low noise amplifier;
a first switch having an input terminal coupled to an output of the power amplifier, a first output terminal, and a second output terminal; and
a second switch having a first terminal coupled to the first output terminal over a first signal path, a second terminal coupled to the second output terminal over a second signal path, a third terminal coupled to an input of the low noise amplifier, and a fourth terminal communicably coupled to the antenna, wherein the first filter is disposed on the first signal path, the second filter is disposed on the second signal path, and the third filter is disposed on the third signal path.

7. The wireless circuitry of claim 6, further comprising:
an additional low noise amplifier coupled to a fifth terminal of the second switch over a fourth signal path.

8. The wireless circuitry of claim 7, wherein the second switch has a first throw that couples the fourth terminal to a selected one of the first terminal and the second terminal and has a second throw that couples the fourth terminal to a selected one of the third terminal and the fifth terminal.

9. The wireless circuitry of claim 7, further comprising:
a fourth filter disposed on the fourth signal path and having a fourth passband that overlaps a receive band of a third frequency band, the receive band of the third frequency band being lower than the receive band of the second frequency band.

10. The wireless circuitry of claim 9, wherein the receive band of the third frequency band partially overlaps the receive band of the first frequency band.

11. The wireless circuitry of claim 1, wherein the first filter comprises a first bandpass filter, the second filter comprises a second bandpass filter, and the third filter comprises a third bandpass filter.

12. A radio-frequency front end (RFFE) module comprising:
a power amplifier;
a first switch having an input terminal coupled to an output of the power amplifier, a first output terminal, and a second output terminal;
a second switch having a first terminal coupled to the first output terminal over a first signal path, a second terminal coupled to the second output terminal over a second signal path, and a third terminal coupled to a third signal path;
a first filter disposed on the first signal path and having a first passband that overlaps a first transmit band of a first frequency band, the first frequency band having a first receive band that is higher than the first transmit band;
a second filter disposed on the second signal path and having a second passband that overlaps a second transmit band of a second frequency band, the second frequency band having a second receive band that is lower than the second transmit band; and
a third filter disposed on the third signal path and having a third passband that overlaps the first receive band and the second receive band.

13. The RFFE module of claim 12, further comprising:
a low noise amplifier having an input coupled to the third signal path.

14. The RFFE module of claim 12, wherein the first passband has a first upper cutoff frequency below the first receive band and the second passband has a first lower cutoff frequency above the second receive band.

15. The RFFE module of claim 14, wherein the third passband has a second lower cutoff frequency above the first transmit band and has a second upper cutoff frequency below the second transmit band.

16. The RFFE module of claim 12, wherein the second switch comprises:
a fourth terminal;
a first throw configured to couple the fourth terminal to the third terminal; and
a second throw configured to couple the fourth terminal to a selected one of the first and second terminals.

17. The RFFE module of claim 16, wherein the fourth terminal is configured to be coupled to an antenna.

18. An electronic device comprising:
an antenna configured to convey radio-frequency signals in a first transmit band, a first receive band, a second transmit band different from the first transmit band, and a second receive band different from the first receive band;
a power amplifier;
a first switch having a first terminal, a second terminal, and a third terminal, the first terminal being coupled to an output of the power amplifier;
a second switch having a fourth terminal coupled to the second terminal over a first signal path, a fifth terminal coupled to the third terminal over a second signal path, a sixth terminal coupled to a third signal path, and a seventh terminal communicably coupled to the antenna;
a first filter disposed on the first signal path and having a first passband overlapping the first transmit band;
a second filter disposed on the second signal path and having a second passband overlapping the second transmit band; and
a third filter disposed on the third signal path and having a third passband overlapping the first receive band and the second receive band.

19. The electronic device of claim 18, wherein the first receive band is higher than the first transmit band, the second receive band is higher than the first receive band, and the second transmit band is higher than the second receive band.

20. The electronic device of claim 19, wherein the third passband has a lower cutoff frequency between the first transmit band and the first receive band and has an upper cutoff frequency between the second receive band and the second transmit band.
